(19) United States
(12) Patent Application Publication
(10) Pub. No.: US 2024/0333249 A1
(43) Pub. Date: Oct. 3, 2024

(54) RESONATOR AND RESONATING DEVICE

(71) Applicant: Murata Manufacturing Co., Ltd., Nagaokakyo-shi (JP)

(72) Inventors: Ryota KAWAI, Nagaokakyo-shi (JP); Fumiya ENDOU, Nagaokakyo-shi (JP)

(21) Appl. No.: 18/738,424

(22) Filed: Jun. 10, 2024

Related U.S. Application Data
(63) Continuation of application No. PCT/JP2022/030297, filed on Aug. 8, 2022.

(30) Foreign Application Priority Data
Dec. 15, 2021 (JP) 2021-203493

(51) Int. Cl. H03H 9/05; H03H 9/10; H03H 9/21

(52) U.S. Cl. CPC H03H 9/0595; H03H 9/1035; H03H 9/21

(57) ABSTRACT

A resonator that includes: a vibrating portion including three or more vibrating arms having respective fixed ends, at least two of the three or more vibrating arms being constructed for out-of-plane bending in different phases, and a base portion having a first end portion to which the fixed ends of the three or more vibrating arms are connected and second end portion facing away from the first end portion; a holding portion that holds the vibrating portion; a support arm having a first end connected to the holding portion and a second end connected to the second end portion of the base portion; and a reducing film on the support arm that reduces a Q value of vibration of the support arm.

### CROSS REFERENCE TO RELATED APPLICATIONS

The present application is a continuation of International application No. PCT/JP2022/030297, filed Aug. 8, 2022, which claims priority to Japanese Patent Application No. 2021-203493, filed Dec. 15, 2021, the entire contents of each of which are incorporated herein by reference.

### TECHNICAL FIELD

The present description relates to a resonator including a plurality of vibrating arms that vibrate in an out-of-plane bending vibration mode and a resonating device.

### BACKGROUND ART

Conventionally, resonating devices to which micro electro mechanical systems (MEMS) technology has been applied are used as, for example, timing devices. Such a resonating device is mounted on a printed circuit board that is built into an electronic device, such as a smartphone. The resonating device includes a lower substrate, an upper substrate that forms a cavity between the upper substrate and the lower substrate, and a resonator disposed in the cavity between the lower substrate and the upper substrate.

For example, Patent Document 1 discloses a resonator that changes the resonant frequency by overexciting vibrating arms to cause adjustment films at the ends of the vibrating arms to come into contact with the upper substrate or the lower substrate in a frequency adjustment process of fine-tuning the resonant frequency of the resonator.

Patent Document 1: International Publication No. 2016/175218

### SUMMARY OF THE DESCRIPTION

On the other hand, when the vibrating arms vibrate in a main mode, vibration in a spurious mode occurs in a portion other than the vibrating arms, such as the support arm. Under certain conditions, vibration in the main mode and vibration in the spurious mode may be coupled to each other.

When coupling between vibration in the spurious mode and vibration in the main mode occurs, there is a risk that, for example, the resonant frequency significantly changes or the equivalent series resistance increases.

The present description addresses the problems described above with an object of providing a resonator and a resonating device that can suppress coupling between vibration in the main mode and vibration in the spurious mode from occurring.

A resonator according to one aspect of the present description includes: a vibrating portion including three or more vibrating arms having respective fixed ends, at least two of the three or more vibrating arms being constructed for out-of-plane bending in different phases, and a base portion having a first end portion to which the fixed ends of the three or more vibrating arms are connected and a second end portion facing away from the first end portion; a holding portion that holds the vibrating portion; a support arm having a first end connected to the holding portion and a second end connected to the second end portion of the base portion; and a reducing film on the support arm that reduces a Q value of vibration of the support arm.

A resonating device according to the aspect of the present description includes the resonator described above.

According to the present description, coupling between vibration in the main mode and vibration in the spurious mode can be prevented from occurring.

### BRIEF DESCRIPTION OF THE DRAWINGS

FIG. 1 is a perspective view schematically illustrating an external appearance of a resonating device according to an embodiment.

FIG. 2 is an exploded perspective view schematically illustrating the structure of the resonating device illustrated in FIG. 1.

FIG. 3 is a plan view schematically illustrating the structure of a resonator illustrated in FIG. 2.

FIG. 4 is a cross-sectional view taken along an X-axis, schematically illustrating a laminated structure of the resonating device illustrated in FIG. 1.

FIG. 5 is a cross-sectional view taken along a Y-axis, schematically illustrating the laminated structure of the resonating device illustrated in FIG. 1.

FIG. 6 is a plan view for describing the dimensions of the resonator illustrated in FIG. 3.

FIG. 7 is a graph illustrating the relationship between an input voltage and a frequency change rate of a virtual resonator.

FIG. 8 is a graph illustrating the relationship between the input voltage and an equivalent series resistance of the virtual resonator.

FIG. 9 is a graph illustrating the relationship between a frequency ratio and a coupling drive level of the virtual resonator.

FIG. 10 is an enlarged main part cross-sectional view schematically illustrating the structure of surroundings of a support rear arm in FIG. 3.

FIG. 11 is a graph illustrating the relationship between the structure of the surroundings of the support arm and the coupling drive level.

### DESCRIPTION OF THE PREFERRED EMBODIMENTS

Embodiments of the present description will be described below. In the following drawings, the same or similar components are denoted by the same or similar reference numerals. Since the drawings are exemplary and the dimensions and shapes of individual portions are schematic, the technical scope of the present description should not be interpreted as being limited to the embodiments.

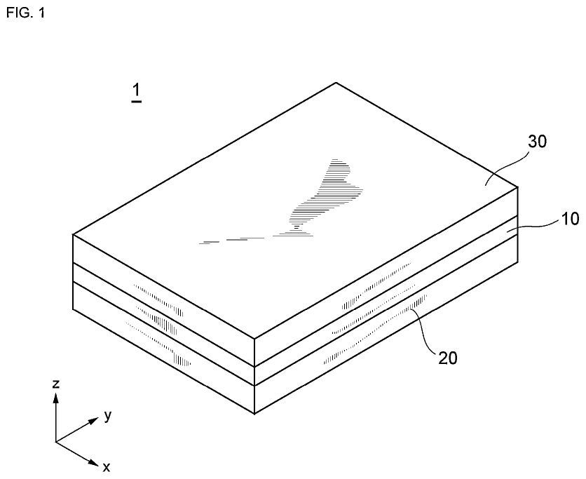

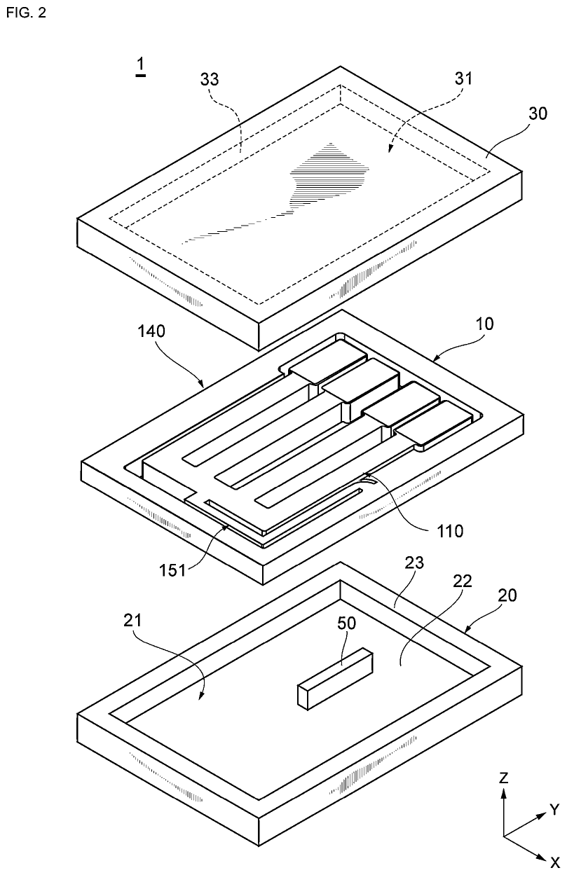

First, a general structure of a resonating device according to an embodiment will be described with reference to FIGS. 1 and 2. FIG. 1 is a perspective view schematically illustrating an external appearance of a resonating device 1 according to an embodiment. FIG. 2 is an exploded perspective view schematically illustrating the structure of the resonating device 1 illustrated in FIG. 1.

The resonating device 1 includes a lower lid 20, a resonator 10, and an upper lid 30. That is, the lower lid 20, the resonator 10, a joint portion 40, which will be described later, and the upper lid 30 are laminated together in this order to form the resonating device 1. The lower lid 20 and the upper lid 30 are disposed to face each other with the resonator 10 therebetween. It should be noted that the upper lid 30 corresponds to an example of the lid body according to the present description.

Components of the resonating device 1 will be described below. It should be noted that, in the following description, the side of the resonating device 1 on which the upper lid 30 is provided is a top (or a front), and the side on which the lower lid 20 is provided is a bottom (or a back).

The resonator 10 is a MEMS vibrator manufactured by using MEMS technology. This MEMS vibrator is applied to, for example, timing devices, RF filters, duplexers, ultrasonic transducers, angular velocity sensors (gyro sensors), acceleration sensors, and the like. In addition, the MEMS vibrator may also be applied to piezoelectric mirrors or piezoelectric gyroscopes that have an actuator function, piezoelectric microphones or ultrasonic vibration sensors that have a pressure sensor function, and the like. Furthermore, the MEMS vibrator may also be applied to electrostatic MEMS vibrators, electromagnetically driven MEMS vibrators, and piezo-resistive MEMS vibrators.

The resonator 10 is joined to the lower lid 20 and the upper lid 30 such that the resonator 10 is sealed and the vibration space for the resonator 10 is formed. In addition, the resonator 10, the lower lid 20, and the upper lid 30 are formed of silicon substrates (referred to below as Si substrates), and these Si substrates are joined to each other. It should be noted that the resonator 10, the lower lid 20, and the upper lid 30 may be formed of SOI (silicon on insulator) substrates in which silicon layers and silicon oxide films are laminated together.

The lower lid 20 includes a rectangular flat-shaped bottom plane 22 provided parallel to an XY plane, and side walls 23 extending in the Z-axis direction from the peripheral edge portions of the bottom plate 22, that is, in a direction in which the lower lid 20 and the resonator 10 are laminated together. The lower lid 20 has a recessed portion 21 defined by the surface of the bottom plate 22 and the inner surfaces of the side walls 23 on the surface facing the resonator 10. The recessed portion 21 forms at least a portion of the vibration space of the resonator 10. It should be noted that the lower lid 20 may have a flat plate structure that does not have the recessed portion 21. In addition, a getter layer may be formed on a surface of the recessed portion 21 of the lower lid 20 close to the resonator 10.

In addition, the lower lid 20 also includes a projecting portion 50 formed on the surface of the bottom plate 22. The detailed structure of the projecting portion 50 will be described later.

The upper lid 30 includes a rectangular flat-shaped bottom plate 32 provided parallel to the XY plane, and side walls 33 extending in the Z-axis direction from the peripheral edge portions of the bottom plate 32. The upper lid 30 has a recessed portion 31 defined by the surface of the bottom plate 32 and the inner surfaces of the side walls 23 on the surface facing the resonator 10. The recessed portion 31 forms at least a portion of the vibration space in which the resonator 10 vibrates. It should be noted that the upper lid 30 may have a flat plate structure that does not have the recessed portion 31. In addition, a getter layer may be formed on a surface of the recessed portion 31 of the upper lid 30 close to the resonator 10.

The vibration space of the resonator 10 is hermetically sealed, and a vacuum state is maintained by the upper lid 30, the resonator 10, and the lower lid 20 being joined together. The vibration space may be filled with a gas, such as an inert gas.

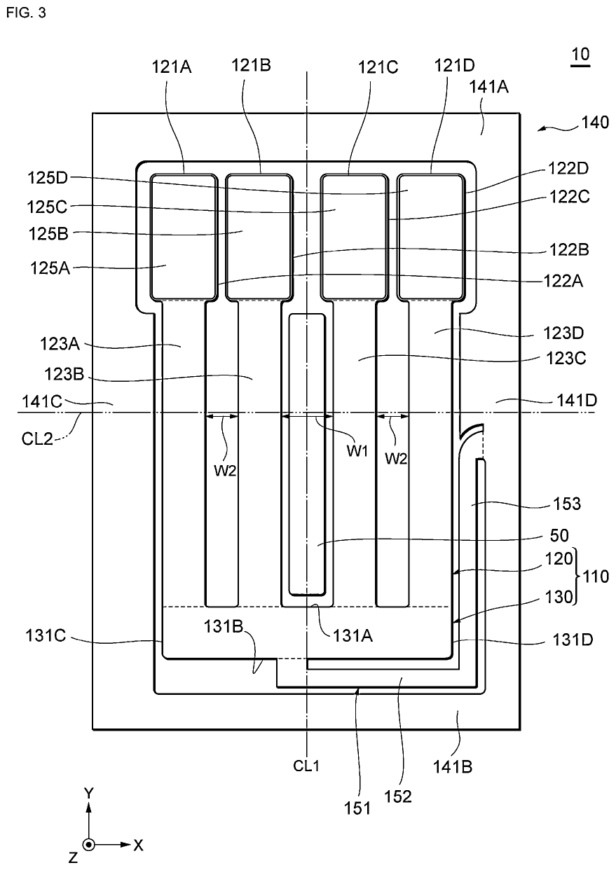

Next, a schematic structure of the resonator according to the first embodiment will be described with reference to FIG. 3. FIG. 3 is a plan view schematically illustrating the structure of the resonator 10 illustrated in FIG. 2.

As illustrated in FIG. 3, the resonator 10 is a MEMS vibrator manufactured by using MEMS technology and vibrates in the XY plane of the orthogonal coordinate system in FIG. 3 by using the out-of-plane bending vibration mode as main vibration (also referred to below as a main mode).

The resonator 10 includes a vibrating portion 110, a holding portion 140, and a support arm 151.

The vibrating portion 110 has a rectangular outline extending parallel to the XY plane of the orthogonal coordinate system in FIG. 3. The vibrating portion 110 is located inward of the holding portion 140, and spaces are formed at predetermined intervals between the vibrating portion 110 and the holding portion 140. In the example in FIG. 3, the vibrating portion 110 includes an exciting portion 120 including four vibrating arms 121A to 121D (also collectively referred to below as the vibrating arms 121) and a base portion 130. It should be noted that the number of the vibrating arms is not limited to four and may be any number not less than, for example, three. In the embodiment, the exciting portion 120 and the base portion 130 are formed integrally.

The vibrating arms 121A, 121B, 121C, and 121D extend in the Y-axis direction and are provided in this order in the X-axis direction at predetermined intervals. One end of the vibrating arm 121A is a fixed end connected to a front-end portion 131A of the base portion 130, which will be described later, and the other end of the vibrating arm 121A is an open end provided away from the front-end portion 131A of the base portion 130. The vibrating arm 121A includes a weight portion 122A close to the open end and an arm portion 123A that extends from the fixed end and is connected to the weight portion 122A. Similarly, the vibrating arms 121B, 121C, and 121D include weight portions 122B, 122C, and 122D and arm portions 123B, 123C, and 123D, respectively. It should be noted that the arm portions 123A to 123D have a width in the X-axis direction of approximately 25 μm and a length in the Y-axis direction of approximately 246 μm.

In the exciting portion 120 according to the embodiment, two vibrating arms 121A and 121D are disposed on the outer side in the X-axis direction, and two vibrating arms 121B and 121C are disposed on the inner side in the X-axis direction. A width W1 (referred to below as a release width) of a gap formed between the arm portions 123B and 123C of the two vibrating arms 121B and 121C on the inner side is set larger than, for example, a release width W2 between the arm portions 123A and 123B of the vibrating arms 121A and 121B adjacent in the X-axis direction and a release width W2 between the arm portions 123D and 123C of the vibrating arms 121D and 121C adjacent in the X-axis direction. The release width W1 is, for example, approximately 38 μm, and the release width W2 is, for example, approximately 17 μm. The vibration characteristics and the durability of the vibrating portion 110 can be improved by setting the release width W1 larger than the release widths W2 as described above. It should be noted that, the release width W1 may be set smaller than or equal to the release width W2 to decrease the size of the resonating device 1.

The weight portions 122A to 122D (also collectively referred to below as the weight portions 122) have mass-adding films 125A to 125D (also collectively referred to below as mass-adding films 125) on the surfaces thereof. Accordingly, the weights per unit length (also simply referred to below as the weight) of the weight portions 122A to 122D are greater than the weights of the arm portions 123A to 123D, respectively. As a result, the vibration characteristics can be improved while the size of the vibrating portion 110 is reduced. In addition, the mass-adding films 125A to 125D have not only the function of increasing the weights of the end portions of the vibrating arms 121A to 121D but also the function of adjusting the resonant frequencies of the vibrating arms 121A to 121D by reducing some portions of the end portions; that is, a function of so-called frequency adjustment films.

In the embodiment, the width of the weight portions 122A to 122D in the X-axis direction is, for example, approximately 46 μm, which is larger than the width of the arm portions 123A to 123D in the X-axis direction. As a result, the weights of the weight portions 122A to 122D can be further increased. The width of the weight portions 122A to 122D in the X-axis direction is preferably more than 1.5 times the width of the arm portions 123A to 123D in the X-axis direction to reduce the size of the resonator 10. However, the weights of the weight portions 122A to 122D need only be greater than the weights of the arm portions 123A to 123D, and the width of the weight portions 122A to 122D in the X-axis direction is not limited to the example in the embodiment. The width of the weight portions 122A to 122D in the X-axis direction may be equal to or smaller than the width of the arm portions 123A to 123D in the X-axis direction.

When the resonator 10 is viewed in plan view from above (simply referred to below as in plan view), the weight portions 122A to 122D have a substantially rectangular shape, and four corners thereof have a rounded shape (a so-called R-shape). Similarly, the arm portions 123A to 123D have a substantially rectangular shape, and portions close to the fixed ends connected to the base portion 130 and portions close to the connection portions connected to the weight portions 122A to 122D have R-shapes. However, the shapes of the weight portions 122A to 122D and the arm portions 123A to 123D are not limited to the example in the embodiment. For example, the shape of the weight portions 122A to 122D may be a substantially trapezoidal shape or a substantially L-shape. In addition, the shape of the arm portions 123A to 123D may be a substantially trapezoidal shape or a substantially L-shape. The weight portions 122A to 122D and the arm portions 123A to 123D may have a bottomed groove portion with an opening in either the front surface or the back surface, or a hole portion with an opening in both the front surface and the back surface. The groove portion and the hole portion may be apart from a side surface connecting the front surface and the back surface to each other and may have an opening in the side surface.

The base portion 130 includes the front-end portion 131A, a rear-end portion 131B, a left end portion 131C, and a right end portion 131D in plan view. As described above, the fixed ends of the vibrating arms 121A to 121D are connected to the front-end portion 131A. The support arm 151 is connected to the rear-end portion 131B.

The front-end portion 131A, the rear-end portion 131B, the left end portion 131C, and the right end portion 131D are some portions of the outer edge portion of the base portion 130. Specifically, the front-end portion 131A and the rear-end portion 131B are end portions extending in the X-axis direction, and the front-end portion 131A and the rear-end portion 131B are disposed so as to face away from each other. The left end portion 131C and the right end portion 131D are end portions extending in the Y-axis direction, and the left end portion 131C and the right end portion 131D are disposed so as to face away from each other. Both ends of the left end portion 131C are connected to one end of the front-end portion 131A and one end of the rear-end portion 131B. Both ends of the right end portion 131D are connected to the other end of the front-end portion 131A and the other end of the rear-end portion 131B.

In plan view, the base portion 130 has a substantially rectangular shape having the front-end portion 131A and the rear-end portion 131B as long sides and the left end portion 131C and the right end portion 131D as short sides. The base portion 130 is formed substantially plane-symmetrically with respect to a virtual plane defined parallel to a center line CL1 disposed centrally in the X-axis direction, which is a perpendicular bisector of the front-end portion 131A and the rear-end portion 131B. That is, it can be said that the base portion 130 is formed substantially line-symmetrically with respect to the center line CL1. It should be noted that the shape of the base portion 130 is not limited to the rectangular shape illustrated in FIG. 3 and may be another shape that is substantially line-symmetrical with respect to the center line CL1. For example, the shape of the base portion 130 may be a trapezoidal shape in which one of the front-end portion 131A and the rear-end portion 131B is longer than the other. In addition, at least one of the front-end portion 131A, the rear-end portion 131B, the left end portion 131C, and the right end portion 131D may be bent or curved.

It should be noted that the virtual plane corresponds to a symmetry plane of the entire vibrating portion 110, and the center line CL1 corresponds to the center line of the entire vibrating portion 110 disposed centrally in the X-axis direction. Accordingly, the center line CL1 is also a line passing through the middle of the vibrating arms 121A to 121D in the X-axis direction and is located between the vibrating arm 121B and the vibrating arm 121C. Specifically, the vibrating arm 121A and the vibrating arm 121B adjacent to each other are formed symmetrically with the vibrating arm 121D and the vibrating arm 121C adjacent to each other, respectively, about the center line CL1.

The base portion length of the base portion 130, which is the longest distance in the Y-axis direction between the front-end portion 131A and the rear-end portion 131B, is, for example, approximately 25 μm. In addition, the base portion width, which is the longest distance in the X-axis direction between the left end portion 131C and the right end portion 131D, is, for example, approximately 172 μm. It should be noted that, in the example illustrated in FIG. 3, the base portion length corresponds to the length of the left end portion 131C or the right end portion 131D, and the base portion width corresponds to the length of the front-end portion 131A or the rear-end portion 131B.

The holding portion 140 holds the vibrating portion 110. More specifically, the holding portion 140 is formed such that the vibrating arms 121A to 121D can vibrate. Specifically, the holding portion 140 is formed plane-symmetrically with respect to the virtual plane defined parallel to the center line CL1. The holding portion 140 has a rectangular frame shape in plan view and is disposed parallel to the XY plane to surround the outline of the vibrating portion 110. Since the holding portion 140 has a frame shape in plan view as described above, the holding portion 140 that surrounds the vibrating portion 110 can be easily achieved.

It should be noted that the holding portion 140 need only be disposed in at least a portion of the perimeter of the vibrating portion 110 and need not have a frame shape. For example, the holding portion 140 need only be disposed in a portion of the perimeter of the vibrating portion 110 such that the holding portion 140 can hold the vibrating portion 110 and can be joined to the upper lid 30 and the lower lid 20.

In the embodiment, the holding portion 140 includes frame bodies 141A to 141D formed integrally. As illustrated in FIG. 3, the frame body 141A is provided to face the open ends of the vibrating arms 121A to 121D with the longitudinal direction thereof parallel to the X-axis. The frame body 141B is provided to face the rear-end portions 131B of the base portion 130 with the longitudinal direction thereof parallel to the X-axis. The frame body 141C is provided to face the left end portion 131C of the base portion 130 and the vibrating arm 121A with the longitudinal direction thereof parallel to the Y-axis, and both ends thereof are connected to ends of the frame bodies 141A and 1418 at both ends thereof. The frame body 141D is provided to face the right end portion 131D of the base portion 130 and the vibrating arm 121A with the longitudinal direction thereof parallel to the Y-axis, and both ends thereof are connected to the other ends of the frame bodies 141A and 141B. The frame body 141A and the frame body 141B face each other in the Y-axis direction with the vibrating portion 110 therebetween. The frame body 141C and the frame body 141D face each other in the X-axis direction with the vibrating portion 110 therebetween.

The support arm 151 is disposed inward of the holding portion 140 and connects the base portion 130 and the holding portion 140 to each other. The support arm 151 is not line-symmetric with respect to the center line CL1 in plan view; that is, the support arm 151 is formed asymmetrically. Specifically, the support arm 151 includes a support rear arm 152 and a support side arm 153.

The support side arm 153 extends parallel to the vibrating arm E 121D between the vibrating arm 121D and the holding portion 140. Specifically, the support side arm 153 extends in the Y-axis direction from one end (a right end or an end close to the frame body 141D) of the support rear arm 152 toward the frame body 141A, is bent in the X-axis direction, and is connected to the frame body 141D. That is, one end of the support arm 151 is connected to the holding portion 140.

The support rear arm 152 extends from the support side arm 153 between the rear-end portion 131B of the base portion 130 and the holding portion 140. Specifically, the support rear arm 152 extends in the X-axis direction from one end (a lower end or an end close to the frame body 141B) of the support side arm 153 toward the frame body 141C. Then, the support rear arm 152 is bent in the Y-axis direction near the middle of the base portion 130 in the X-axis direction, extends parallel to the center line CL1, and is connected to the rear-end portion 131B of the base portion 130. That is, the other end of the support arm 151 is connected to the rear-end portion 131B of the base portion 130.

The projecting portion 50 projects into the vibration space from the recessed portion 21 of the lower lid 20. The projecting portion 50 is disposed between the arm portion 123B of the vibrating arm 121B and the arm portion 123C of the vibrating arm 121C in plan view. The projecting portion 50 extends parallel to the arm portions 123B and 123C in the Y-axis direction and is formed in a prismatic shape. The length of the projecting portion 50 in the Y-axis direction is approximately 200 μm and the length in the X-axis direction is approximately 15 μm. It should be noted that the number of the projecting portions 50 is not limited to one and may be two or more. Since the projecting portion 50 is disposed between the vibrating arm 121B and the vibrating arm 121C and projects from the bottom plate 22 of the recessed portion 21, the rigidity of the lower lid 20 can be increased, and deflection of the resonator 10 formed on the lower lid 20 and warping of the lower lid 20 can be suppressed from occurring.

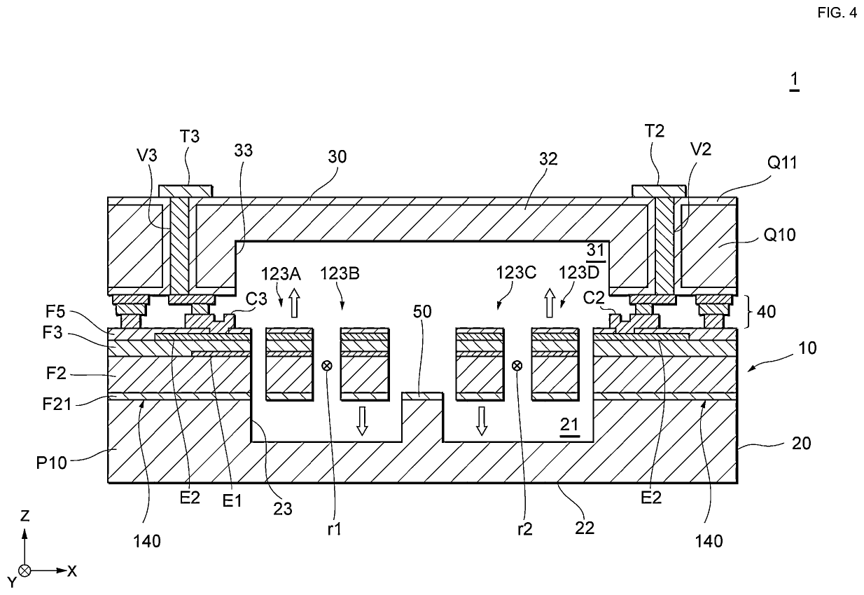

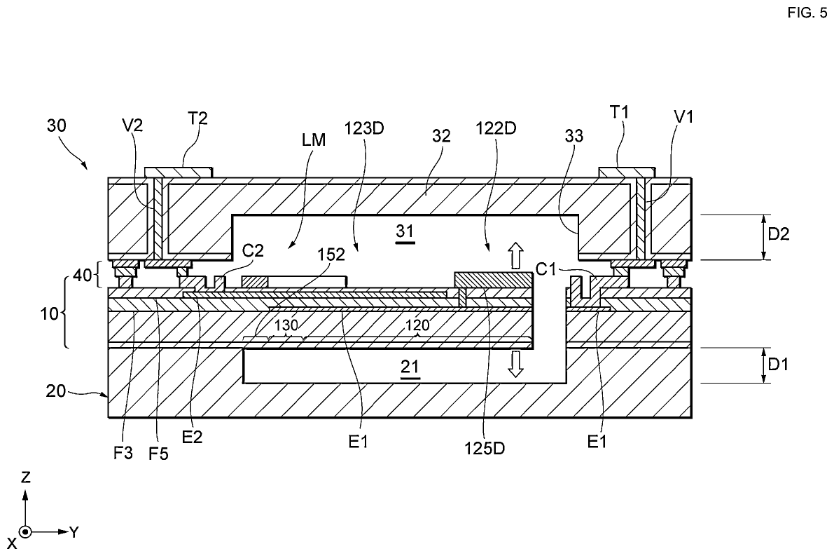

Next, the laminated structure and the operation of the resonating device according to the first embodiment will be described with reference to FIGS. 4 and 5. FIG. 4 is a cross-sectional view taken along the X-axis, schematically illustrating the laminated structure of the resonating device 1 in FIG. 1. FIG. 5 is a cross-sectional view taken along the Y-axis, schematically illustrating the laminated structure of the resonating device 1 illustrated in FIG. 1. The cross section in FIG. 5 is parallel to the frame body 141D and passes through the vibrating arm 121D.

As illustrated in FIGS. 4 and 5, in the resonating device 1, the holding portion 140 of the resonator 10 is joined to the side walls 23 of the lower lid 20, and the holding portion 140 of the resonator 10 is joined to the side walls 33 of the upper lid 30. As described above, the resonator 10 is held between the lower lid 20 and the upper lid 30, and the vibration space in which the vibrating portion 110 vibrates is formed by the lower lid 20, the upper lid 30, and the holding portion 140 of the resonator 10.

The vibrating portion 110, the holding portion 140, and the support arm 151 of the resonator 10 are formed integrally by a single process. In the resonator 10, a metal film E1 is laminated on a Si substrate F2, which is an example of the substrate. In addition, a piezoelectric film F3 is laminated on the metal film E1 to cover the metal film E1, and a metal film E2 is laminated on the piezoelectric film F3. A protective film F5 is laminated on the metal film E2 to cover the metal film E2. In the weight portions 122A to 122D, the mass-adding films 125A to 125D described above are laminated on the protective films F5. The external shapes of the vibrating portion 110, the holding portion 140, and the support arm 151 are formed by patterning a laminated body including the Si substrate F2, the metal film E1, the piezoelectric film F3, the metal film E2, the protective film F5, and the like by using removal processing, such as dry etching.

An example in which the resonator 10 includes the metal film E1 is adopted in the embodiment, but the present description is not limited to this example. For example, in the resonator 10, when a degenerate silicon substrate with low resistance is used as the Si substrate F2, the Si substrate F2 can also serve as the metal film E1, and the metal film E1 may be omitted.

The Si substrate F2 is made of, for example, a degenerate n-type silicon (Si) semiconductor having a thickness of approximately 6 um and may contain phosphorus (P), arsenic (As), antimony (Sb), or the like as an n-type dopant. In addition, the resistance value of the degenerate silicon (Si) used in the Si substrate F2 is, for example, less than 1.6 mΩ·cm, more preferably 1.2 mΩ·cm or less.

Furthermore, on the lower surface of the Si substrate F2, a silicon oxide layer F21 made of, for example, SiO₂ is formed as an example of a temperature characteristics correction layer. As a result, the temperature characteristics can be improved.

In the embodiment, the silicon oxide layer F21 decreases the temperature coefficient of the frequency in the vibrating portion 110 when a temperature correction layer is formed in the Si substrate F2, that is, the change rate per temperature, to be close to at least room temperature compared with the case in which the silicon oxide layer F21 is not formed in the Si substrate F2. Since the vibrating portion 110 includes the silicon oxide layer F21, it is possible to decrease changes with temperature at the resonant frequency of a laminated structure body including, for example, the Si substrate F2, the metal films El and E2, the piezoelectric film F3, and the silicon oxide layer F21. The silicon oxide layer may be formed on the upper surface of the Si substrate F2 or may be formed on both the upper surface and the lower surface of the Si substrate F2.

The silicon oxide layers F21 of the weight portions 122A to 122D are preferably formed to have a uniform thickness. It should be noted that “uniform thickness” indicates that variations in the thicknesses of the silicon oxide layers F21 fall within ±20% of the average of the thicknesses of the silicon oxide layers F21.

Each of the metal films El and E2 includes an excitation electrode that excites the vibrating arms 121A to 121D and an extended electrode that electrically connects the excitation electrode and an external power source to each other. The portions of the metal films El and E2 that serve as the exciting electrodes face each other with the piezoelectric film F3 therebetween in the arm portions 123A to 123D of the vibrating arms 121A to 121D. The portions of the metal films E1 and E2 that serve as the extended electrodes are drawn from the base portion 130 to the holding portion 140 through, for example, the support arm 151. The metal film E1 is electrically continuous throughout the resonator 10. The portions of the metal film E2 that are formed on the vibrating arms 121A and 121D are electrically separated from the portions of the metal film E2 that are formed on the vibrating arms 121B and 121C.

The thickness of the metal films E1 and E2 are, for example, 0.1 μm to 0.2 μm. After being formed, the films E1 and E2 are subjected to patterning by removal processing, such as etching, to form the exciting electrodes, the extended electrodes, and the like. The metal films E1 and E2 are made of, for example, a metal material having a body-centered cubic crystal structure. Specifically, the metal films E1 and E2 are made of Mo (molybdenum), tungsten (W), or the like. Since the metal films E1 and E2 include mainly a metal having a body-centered cubic crystal structure, the metal films E1 and E2 that are suitable for the lower electrode and upper electrode of the resonator 10 can be easily achieved.

The piezoelectric film F3 is a thin film made of a piezoelectric substance that performs mutual conversion between electrical energy and mechanical energy. The piezoelectric film F3 expands and contracts in the Y-axis direction of the in-plane directions of the XY plane in accordance with the electric field generated in the piezoelectric film F3 by the metal films E1 and E2. As the piezoelectric film F3 expands and contracts as described above, the open ends of the vibrating arms 121A to 121D are displaced toward the bottom plate 22 of the lower lid 20 and the bottom plate 32 of the upper lid 30. As a result, the resonator 10 vibrates in the vibration mode of out-of-plane bending.

The thickness of the piezoelectric film F3 is, for example, approximately 1 μm but may be approximately 0.2 μm to 2 μm. The piezoelectric film F3 is made of a material having a wurtzite hexagonal crystal structure, and the material may include mainly nitride or oxide, such as aluminum nitride (AlN), scandium aluminum nitride (ScAlN), zinc oxide (ZnO), gallium nitride (GaN), indium nitride (InN), or the like. It should be noted that scandium aluminum nitride is formed by some aluminum in aluminum nitride being replaced with scandium, but some aluminum in aluminum nitride may be replaced with two elements instead of one element, such as magnesium (Mg) and niobium (Nb), or magnesium (Mg) and zirconium (Zr). As described above, the piezoelectric film F3 suitable for the resonator 10 can be easily achieved by including mainly a piezoelectric substance having a wurtzite hexagonal crystal structure.

The protective film F5 protects the metal film E2 from oxidation. It should be noted that the protective film F5 need not be exposed to the bottom plate 32 of the upper lid 30 as long as the protective film F5 is provided on the upper lid 30. For example, a parasitic capacitance reducing film or the like that decreases the capacitance of wiring formed in the resonator 10 may be formed to cover the protective film F5. The protective film F5 is formed of a piezoelectric film made of, for example, aluminum nitride (AlN), scandium aluminum nitride (ScAlN), zinc oxide (ZnO), gallium nitride (GaN), indium nitride (InN) or an insulating film made of silicon nitride (SiN), silicon oxide (SiO₂), alumina oxide (Al₂O₃), tantalum pentoxide (Ta₂O₅), or the like. The thickness of F5 of the protective film is equal to or less than half the thickness of the piezoelectric film F3 and is, for example, approximately 0.2 μm in the embodiment. More preferably, the thickness of the protective film F5 is approximately one-fourth the thickness of the piezoelectric film F3. Furthermore, when the protective film F5 is made of a piezoelectric substance, such as aluminum nitride (AlN), the piezoelectric substance preferably has the same orientation as the piezoelectric film F3.

The protective films F5 of the weight portions 122A to 122D are desirably formed to have a uniform thickness. It should be noted that “uniform thickness” indicates that variations in the thicknesses of the protective films F5 fall within ±20% of the average of the thicknesses of the protective films F5.

The mass-adding films 125A to 125D form the surfaces of the respective weight portions 122A to 122D close to the upper lid 30 and correspond to the frequency adjustment films of the respective vibrating arms 121A to 121D. The resonant frequency of the resonator 10 is adjusted by trimming processing that removes some portions of the mass-adding films 125A to 125D. In terms of the efficiency of frequency adjustment, the mass-adding films 125A to 125D are preferably formed of a material that has a higher mass reduction rate of etching than the protective film F5. The mass reduction rate is obtained as the product of the etching rate and the density. The etching rate is the thickness removed per unit time. When the mass reduction rate of the mass-adding films 125A to 125D is higher than that of the protective film F5 as described above, the etching rate of the mass-adding films 125A to 125D may be greater or smaller than that of the protective film F5. In addition, to efficiently increase the weights of the weight portions 122A to 122D, the mass-adding films 125A to 125D are preferably made of a material with a high specific gravity. For these reasons, the mass-adding films 125A to 125D are made of a metal material, such as molybdenum (Mo), tungsten (W), gold (Au), platinum (Pt), nickel (Ni), aluminum (Al), or titanium (Ti).

Some portions of the upper surfaces of the mass-adding films 125A to 125D are removed by trimming processing in the process of adjusting the frequency. The trimming processing of the mass-adding films 125A to 125D can be performed by dry etching that applying, for example, an argon (Ar) ion beam. An ion beam has high processing efficiency because the irradiation area thereof is wide, but the mass-adding films 125A to 125D may be electrically charged by an ion beam. The mass-adding films 125A to 125D are preferably grounded to prevent the vibration characteristics of the resonator 10 from degrading because the vibratory tracks of the vibrating arms 121A to 121D are changed by coulomb interactions due to the electrically charged mass-adding films 125A to 125D.

Leader lines C1, C2, and C3 are formed on the protective film F5 of the holding portion 140. The leader line C1 is electrically connected to the metal film E1 through a through-hole formed in the piezoelectric film F3 and the protective film F5. The leader line C2 is electrically connected to portions of the metal film E2 that are formed in the vibrating arms 121A and 121D through through-holes formed in the protective film F5. The leader line C3 is electrically connected to portions of the metal film E2 that are formed in the vibrating arms 121B and 121C through through-holes formed in the protective film F5. The leader lines C1 to C3 are made of a metal material, such as aluminum (Al), germanium (Ge), gold (Au), or tin (Sn).

In the embodiment, an example in which the arm portions 123A to 123D, the leader lines C2 and C3, through-electrodes V2 and V3, and the like are located on a cross-section of a single plane is illustrated in FIG. 4, but these components are not necessarily located on a cross-section of a single plane. For example, the through-electrodes V2 and V3 may be formed at a position away in the Y-axis direction from a cross-section that is parallel to the ZX plane defined by the Z-axis and the X-axis and cuts the arm portions 123A to 123D.

Similarly, in the embodiment, an example in which a weight portion 122D, the arm portion 123D, the leader lines C1 and C2, through-electrodes V1 and V2, and the like are located on a cross-section of a single plane is illustrated in FIG. 5, but these components are not necessarily located on a cross-section of a single plane.

The bottom plate 22 and the side walls 23 of the lower lid 20 are formed integrally with each other as a Si substrate P10. The Si substrate P10 is made of non-degenerate silicon and has a resistivity of, for example, 10 Ω·cm or greater. The Si substrate P10 is exposed to the inside of the recessed portion 21 of the lower lid 20. The silicon oxide layer F21 is formed on the upper surface of the projecting portion 50. However, to suppress the projecting portion 50 from being electrically charged, the Si substrate P10 having a lower electric resistivity than the silicon oxide layer F21 may be exposed or a conductive layer may be formed on the upper surface of the projecting portion 50.

The thickness of the lower lid 20 in the Z-axis direction is approximately 150 μm, and the depth of the recessed portion 21 in the Z-axis is approximately 50 μm.

The bottom plate 32 and the side walls 33 of the upper lid 30 are formed integrally as a Si substrate Q10. The front surface and the back surface of the upper lid 30 and the inner surface of the through-hole are preferably covered with a silicon oxide film Q11. The silicon oxide film Q11 is formed on the surface of the Si substrate Q10 by, for example, oxidation of the Si substrate Q10 or chemical vapor deposition (CVD). The Si substrate Q10 is exposed to the inside of the recessed portion 31 of the upper lid 30. It should be noted that a getter layer may be formed on a surface of the recessed portion 31 of the upper lid 30 that faces the resonator 10. The getter layer is made of, for example, titanium (Ti) or the like and adsorbs an out gas emitted from the joint portion 40, which will be described later, and suppresses the degree of vacuum of the vibration space from being decreased. It should be noted that the getter layer may be formed on a surface of the recessed portion 21 of the lower lid 20 that faces the resonator 10 or may be formed on surfaces of both the recessed portion 21 of the lower lid 20 and the recessed portion 31 of the upper lid 30 that face the resonator 10.

The thickness of the upper lid 30 in the Z-axis direction is approximately 150 μm, and the depth of the recessed portion 31 in the Z-axis direction is approximately 50 μm.

Terminals T1, T2, and T3 are formed on the upper surface (the surface facing away from the surface facing the resonator 10) of the upper lid 30. The terminal T1 is a mounting terminal through which the metal film E1 is grounded. The terminal T2 is a mounting terminal through which the metal films E2 of the vibrating arms 121A and 121D are electrically connected to an external power supply. The terminal T3 is a mounting terminal through which the metal films E2 of the vibrating arms 121B and 121C are electrically connected to the external power supply. The terminals T1 to T3 are formed by plating nickel (Ni), gold (Au), silver (Ag), copper (Cu), or the like on a metallized layer (base layer) made of, for example, chromium (Cr), tungsten (W), nickel (Ni), or the like. It should be noted that a dummy terminal electrically insulated from the resonator 10 may be formed on the upper surface of the upper lid 30 to adjust the parasitic capacitance and the balance of mechanical strength.

The through-electrodes V1, V2, and V3 are formed in the side walls 33 of the upper lid 30. The through-electrode V1 electrically connects the terminal T1 and the leader line C1 to each other, the through-electrode V2 electrically connects the terminal T2 and the leader line C2 to each other, and the through-electrode V3 electrically connects the terminal T3 and the leader line C3 to each other. Through-holes passing through the sidewall 33 of the upper lid 30 in the Z-axis direction are filled with a conductive material to form the through-electrodes V1 to V3. The conductive material that fills the through-holes is, for example, polycrystalline silicon (poly-Si), copper (Cu), gold (Au), or the like.

The joint portion 40 is formed between the side walls 33 of the upper lid 30 and the holding portion 140, and the joint portion 40 joins the upper lid 30 and the resonator 10 to each other. The joint portion 40 is formed in a closed ring shape surrounding the vibrating portion 110 on the XY plane so as to hermetically seal the vibration space of the resonator 10 under vacuum. The joint portion 40 is formed of a metal film in which, for example, an aluminum (Al) film, a germanium (Ge) film, and an aluminum (Al) film are laminated in this order and eutectically bonded with each other. It should be noted that the joint portion 40 may be formed by a combination of films appropriately selected from a gold (Au) film, a tin (Sn) film, a copper (Cu) film, a titanium (Ti) film, a silicon (Si) film, and the like. In addition, the joint portion 40 may include a metal compound, such as titanium nitride (TiN) or tantalum nitride (TaN), between films to improve the adhesiveness.

As illustrated in FIG. 5, the support arm 151 includes a reducing film LM. The reducing film LM reduces the Q value of vibration of the support arm 151. More specifically, the reducing film LM is formed on both the support rear arm 152 and the support side arm 153.

The reducing film LM is preferably made of a material with a small Q value of vibration. Specifically, the reducing film is made of, for example, tetraethyl orthosilicate (Si(OC₂H₅)₄), which is also referred to as tetraethoxysilane (TEOS). In addition, the reducing film LM may include a plurality of layers in which, for example, a tetraethyl orthosilicate layer and an aluminum (Al) layer in this order, or a tetraethyl orthosilicate layer, an aluminum (Al) layer, a titanium (Ti) layer, and an aluminum (Al) layer in this order.

In addition, the reducing film LM preferably includes a layer made of a material of the joint portion 40. Specifically, for example, when an aluminum (Al) film is formed on the holding portion 140 of the resonator 10, a germanium (Ge) film is formed on the side walls 33 of the upper lid 30, and the aluminum (Al) film close to the resonator 10 and the germanium (Ge) film close to the upper lid 30 are eutectically bonded with each other to form the joint portion 40, the reducing film LM includes the aluminum (Al) layer. As a result, since the reducing film LM can be formed by, for example, changing the shape of the mask or the like when layers that constitute the joint portion 40 are formed, the reducing film LM can be easily formed without the manufacturing process of the resonator 10 being added or changed.

As described above, the support arm 151 includes the silicon oxide layer F21, the Si substrate F2, the piezoelectric film F3, the metal film E2, and the protective film F5 and has substantially the same laminated structure as the arm portion 123 of the vibrating arm 121. Accordingly, the thickness of the support arm 151 including the reducing film LM is greater than the thickness of the arm portion 123 of the vibrating arm 121.

In the embodiment, the terminal T1 is grounded, and AC voltages of opposite phases are applied to the terminal T2 and the terminal T3. Accordingly, the phase of an electric field generated in the piezoelectric films F3 of the vibrating arms 121A and 121D is opposite to the phase of an electric field generated in the piezoelectric films F3 of the vibrating arms 121B and 121C. As a result, the vibrating arms 121A and 121D on the outer side and the vibrating arms 121B and 121C on the inner side are displaced in opposite directions.

For example, as illustrated in FIG. 4, when the weight portions 122A and 122D and the arm portions 123A and 123D of the vibrating arms 121A and 121D are displaced toward the inner surface of the upper lid 30, the weight portions 122B and 122C and the arm portions 123B and 123C of the vibrating arms 121B and 121C are displaced toward the inner surface of the lower lid 20. Although not illustrated in the drawings, conversely, when the weight portions 122A and 122D and the arm portions 123A and 123D of the vibrating arms 121A and 121D are displaced toward the inner surface of the lower lid 20, the weight portions 122B and 122C and the arm portions 123B and 123C of the vibrating arms 121B and 121C are displaced toward the inner surface of the upper lid 30. As a result, at least two of the four vibrating arms 121A to 121D are subjected to out-of-plane bending at different phases.

As described above, the vibrating arms 121A and 121B vibrate in vertically opposite directions about a central axis r1 extending in the Y-axis direction between the vibrating arms 121A and 121B adjacent to each other. In addition, the vibrating arms 121C and 121D vibrate in vertically opposite directions about a central axis r2 extending in the Y-axis direction between the vibrating arms 121C and 121D adjacent to each other. As a result, twisting moments in opposite directions about the central axis r1 and the central axis r2 are generated, and bending vibration of the vibrating portion 110 occurs. The maximum amplitude of the vibrating arms 121A to 121D is approximately 50 μm, and the amplitude during normal driving is approximately 10 μm.

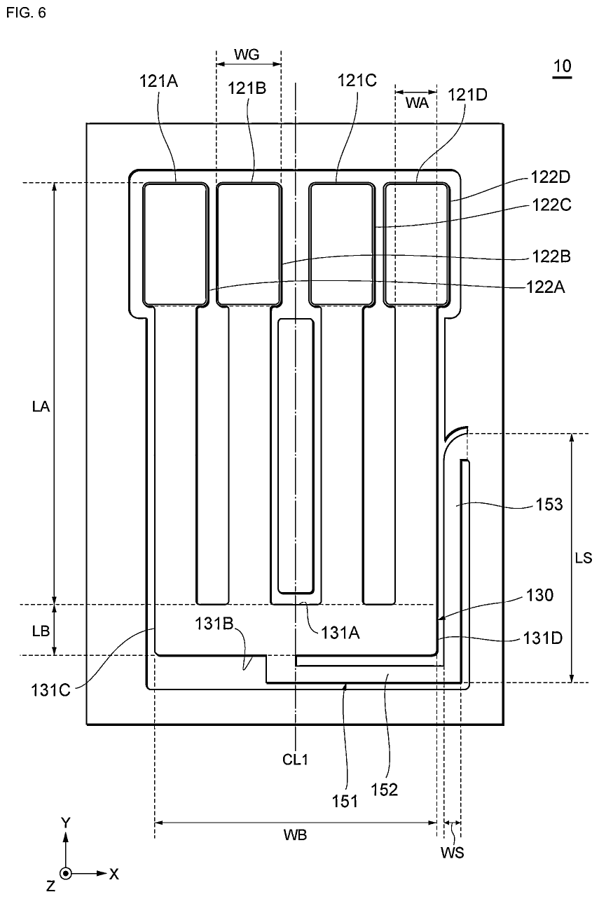

Next, the dimensions of the vibrating portion in plan view will be described with reference to FIG. 6. FIG. 6 is a plan view for describing the dimensions of the resonator 10 illustrated in FIG. 3. It should be noted that FIG. 6 illustrates a portion of the resonator 10 for the sake of simplicity.

As illustrated in FIG. 6, in the resonator 10 according to the embodiment, a width WG, which is the length of the weight portions 122A to 122D in the X-axis direction, is, for example, 46 μm. In addition, a vibrating arm width WA, which is the length of the vibrating arms 121A to 121D in the X-axis direction, is, for example, 25 μm, and a vibrating arm length LA, which is the length of the vibrating arms 121A to 121D in the Y-axis direction, is, for example, 410 μm.

In addition, a base portion length LB, which is the length of the base portion 130 in a direction from the front-end portion 131A to the rear-end portion 131B, is, for example, 25 μm. On the other hand, a base portion width WB, which is the length in a direction from the left end portion 131C to the right end portion 131D, is, for example, 172 μm.

In addition, a support arm width WS, which is the width of the support arm 151 (specifically the length of the support side arm 153 in the X-axis direction), is, for example, 17 μm. Although not illustrated in the drawing, the length of the support rear arm 152 in the Y-axis direction is also 17 μm. In addition, a support arm length LS, which is the length of the support arm 151 (specifically the length of the support side arm 153 in the Y-axis direction), is, for example, 40 μm.

The other end of the support arm 151, specifically the other end of the support rear arm 152, is connected to a portion of the rear-end portion 131B of the base portion 130 shifted 10 μm to the negative side in the X-axis direction, that is, to the left side from the portion through which the center line CL1 passes. In the following description, unless otherwise specified, the portion of the rear-end portion 131B of the base portion 130 through which the center line CL1 passes is assumed to be the origin (zero), and one side (right side) is represented as “+” (positive) and the other side (left side) is represented as “−” (negative). That is, in the example illustrated in FIG. 6, the other end of the support rear arm 152 is connected to the portion shifted −10 μm from the portion of the rear-end portion 131B of the base portion 130 through which the center line CL1 passes.

It should be noted that, in the following description, unless otherwise specified, the dimensions of portions are the lengths described with reference to FIG. 6.

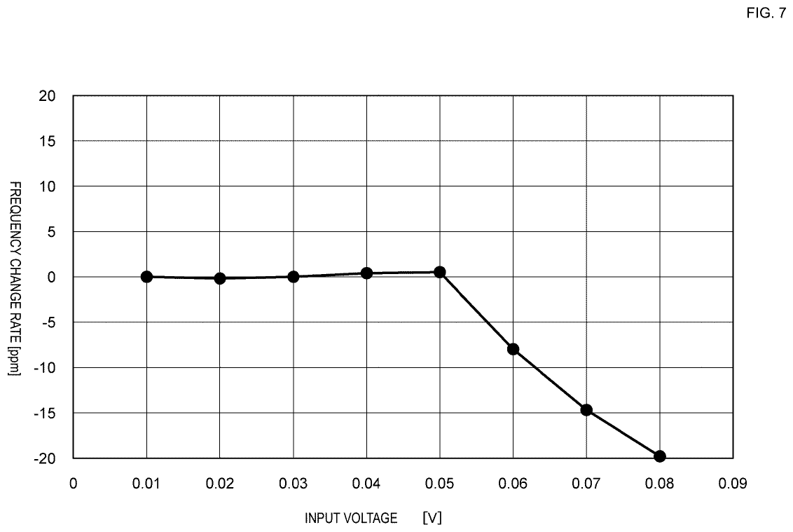

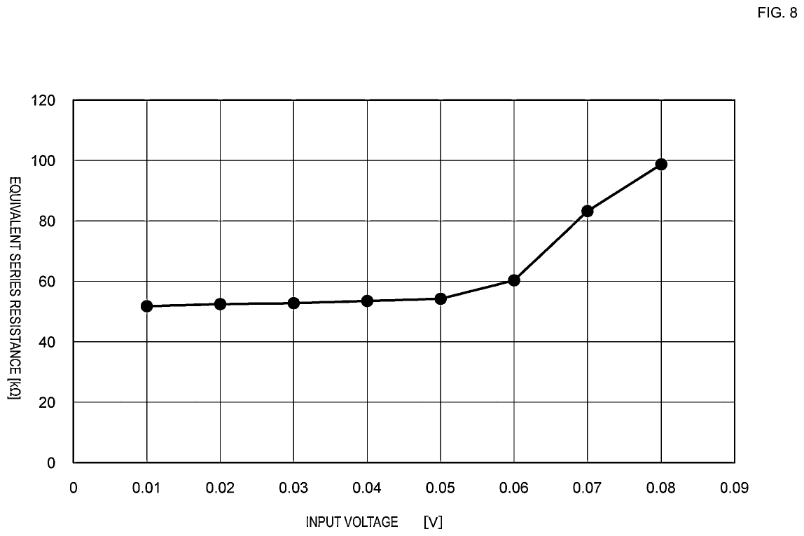

Next, effects of coupling between vibration in the main mode and vibration in the spurious mode will be described with reference to FIGS. 7 and 8. FIG. 7 is a graph illustrating the relationship between an input voltage and a frequency change rate of a virtual resonator. FIG. 8 is a graph illustrating the relationship between the input voltage and an equivalent series resistance of the virtual resonator. It should be noted that the virtual resonator is assumed for comparison with the resonator 10 according to the embodiment and has substantially the same structure as the resonator 10 except that the reducing film LM is not present. In FIGS. 7 and 8, the horizontal axis represents the input voltage (Vin) to be applied to the vibrating arms of the vibrating portion. In addition, in FIG. 7, the vertical axis represents the frequency change rate df/f with respect to the resonant frequency f when the input voltage is 0.01 V. Furthermore, in FIG. 8, the vertical axis represents the equivalent series resistance ESR of the vibrating portion.

As illustrated in FIG. 7, when the input voltage Vin is changed from 0.01 V to 0.05 V by an impedance analyzer in the virtual resonator, the frequency change rate is substantially zero and is nearly unchanged. On the other hand, when an input voltage of 0.05 V to 0.08 V is applied by an impedance analyzer, the frequency change rate significantly changes to negative values. That is, when the input voltage exceeds 0.05 V, the resonant frequency shifts in a negative direction.

In addition, as illustrated in FIG. 8, when the input voltage Vin is changed from 0.01 V to 0.05 V in the virtual resonator by an impedance analyzer, the value of the equivalent series resistance is substantially constant and does not change much. On the other hand, when an input voltage of 0.05 V to 0.08 V is applied by an impedance analyzer, the equivalent series resistance increases as the input voltage increases.

In accordance with these results, in the virtual resonator, when an input voltage higher than 0.05 V is applied, it is thought that coupling between vibration in the main mode and vibration in the spurious mode occurs.

As described above, in the resonator 10 according to the embodiment, the vibrating arms 121A and 121D and the vibrating arms 121B and 121C are subjected to out-of-plane bending vibration in opposite phases in vibration in the main mode. In general, any resonator has vibration that differs from the vibration in the main mode, that is, vibration in the spurious mode (also referred to as parasitic vibration). In the resonator 10 according to the embodiment, the vibrating arm 121 vibrates mainly in the main mode, and the base portion 130 and the support arm 151 vibrate mainly in the spurious mode. This is also the same as with the virtual resonator.

It is known that, when the frequency of vibration in the spurious mode is equal to the number obtained by multiplying the frequency of vibration in the main mode, that is, the resonant frequency, by a predetermined number or the number obtained by dividing the frequency of vibration in the main mode by the predetermined number, coupling between vibration in the main mode and vibration in the spurious mode tend to occur.

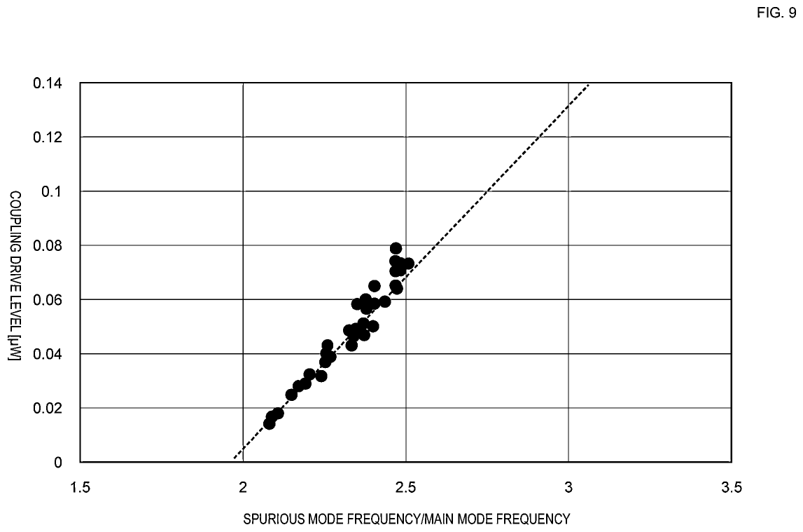

Next, the drive level at which coupling between vibration in the main mode and vibration in the spurious mode occurs will be described with reference to FIG. 9. FIG. 9 is a graph illustrating the relationship between a frequency ratio and a coupling drive level of the virtual resonator. In FIG. 9, the horizontal axis represents the frequency ratio Fs/Fm of the frequency Fs in the spurious mode to the frequency Fm in the main mode. In addition, the vertical axis represents the coupling drive level at which coupling between vibration in the main mode and vibration in the spurious mode occurs. The drive level is the value Vin²/Rr obtained by dividing the square of the input voltage Vin by the resonant resistance Rr and the unit is μW. FIG. 9 is a graph plotting the measured coupling drive levels of a plurality of virtual resonators having different frequency ratios.

As illustrated in FIG. 9, in the virtual resonators, as the frequency ratios become greater than 2, the coupling drive level increases. In other words, when the frequency of vibration in the spurious mode is sufficiently higher than twice the frequency of vibration in the main mode, the coupling drive level becomes higher and coupling between vibration in the main mode and vibration in the spurious mode less likely to occur.

In the virtual resonators, for example, the average of the frequency ratios is 2.37, which is greater than 2. However, occurrence of coupling between vibration in the main mode and vibration in the spurious mode depends on not only the frequency ratio but also other factors. Accordingly, in the virtual resonators, the average of coupling drive levels is 0.058 μW, which is a relatively low value. In addition, since resonators have been required to have a smaller size, it is difficult to significantly increase the frequency ratio by changing the dimensions and the like.

The inventors of the present description have focused on the Q value of vibration in the spurious mode and found that the coupling drive level can be increased by reduction in the Q value. More specifically, the inventors have found that the support arm 151 preferably has the reducing film LM that reduces the Q value of vibration of the support arm 151. This reduces the Q value of vibration in the spurious mode in which vibration of the support arm 151 is main vibration.

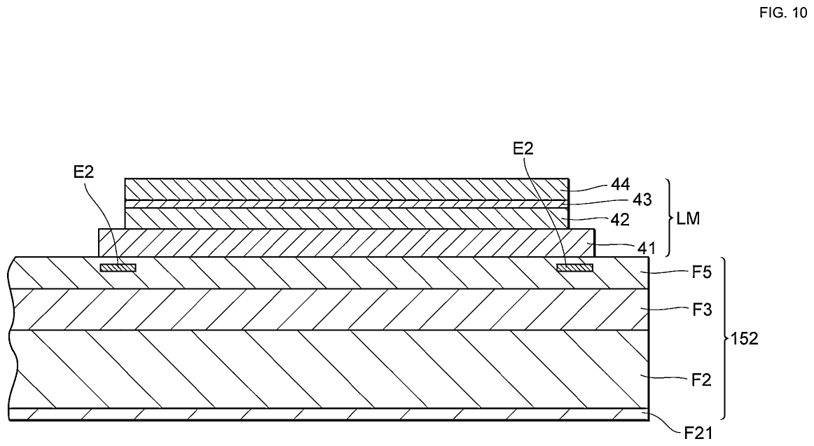

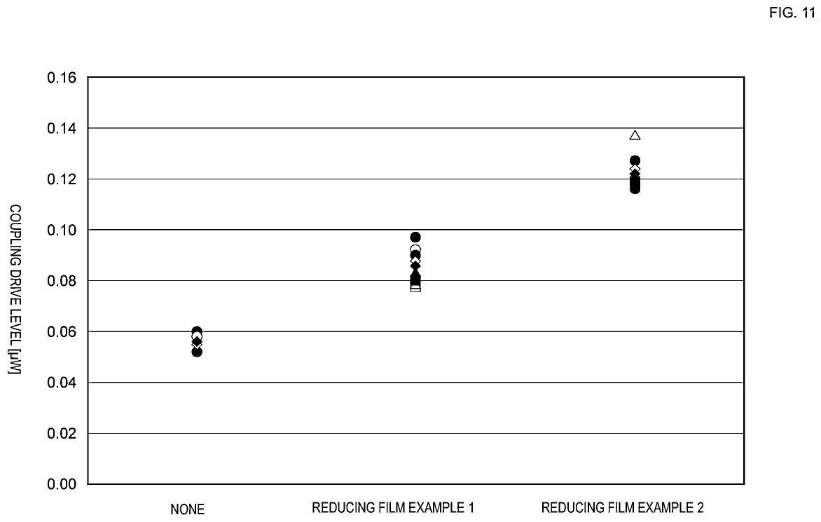

Next, the laminated structure of surroundings of the support arm according to one embodiment of the present description will be described with reference to FIGS. 10 and 11. FIG. 10 is an enlarged main part cross-sectional view schematically illustrating the structure of surroundings of the support rear arm 152 in FIG. 3. FIG. 11 is a graph illustrating the relationship between the structure of the surroundings of the support arm and the coupling drive level. In FIG. 11, the vertical axis represents the coupling drive level at which coupling between vibration in the main mode and vibration in the spurious mode occurs. The drive level is a value Vin²/Rr in μW obtained by square of the input voltage Vin being divided by the resonant resistance Rr. In addition, “NONE” on the horizontal axis represents a virtual resonator in which the support arm does not have the reducing film, and “REDUCING FILM EXAMPLE” and “REDUCING FILM EXAMPLE” on the horizontal axis represent the resonators 10 that include the reducing films LM with different structures on the support arms 151. FIG. 11 is a graph plotting the measured coupling drive levels of the plurality of virtual resonators and the resonators 10.

As illustrated in FIG. 10, unlike the virtual resonator, the support arm 151 according to the embodiment has the reducing film LM. FIG. 10 illustrates the reducing film LM of the support rear arm 152 of the support arm 151.

As described above, the support rear arm 152 includes the Si substrate F2 having the silicon oxide layer F21 on the lower surface thereof, the piezoelectric film F3, and the protective film F5 laminated to cover the metal film E2. The reducing film LM is formed on the support rear arm 152.

The reducing film LM is preferably formed above at least the support rear arm 152 of the support arm 151. The inventors of the present description have found that the thickness, the material, and the like of the connecting portion of the support arm 151 connected to the base portion 130 are dominant factors in reducing the Q value of vibration of the support arm 151. Accordingly, the Q value in the spurious mode in which vibration of the support arm 151 is main vibration can be reduced effectively and efficiently by the reducing film LM being formed at least above the support rear arm 152.

In addition, as described above, the thickness of the support rear arm 152 including the reducing film LM is greater than the thickness of the arm portion 123 of the vibrating arm 121. As a result, Young's modulus of the support arm 151 including the reducing film LM can be increased, and the frequency in the spurious mode relative to the frequency in the main mode can be increased.

The reducing film LM includes a first layer 41, a second layer 42, a third layer 43, and a fourth layer 44. The first layer 41 is a layer including mainly, for example, tetraethyl orthosilicate and has a thickness of 1 μm. The second layer 42 is a layer including mainly, for example, aluminum (Al) and has a thickness of 0.7 μm. The third layer 43 is a layer including mainly, for example, titanium (Ti) and has a thickness of 0.1 μm. The fourth layer 44 is a layer including mainly, for example, aluminum (Al) as in the second layer 42 and has a thickness of 0.7 μm.

As described above, the material of the reducing film LM preferably differs from the material of the arm portion 123 of the vibrating arm 121. As a result, the Q value of vibration in the spurious mode can be decreased while the Q value of vibration in the main mode is increased.

In the following description, unless otherwise specified, the reducing film LM is assumed to have the structure and the thickness described with reference to FIG. 10.

As illustrated in FIG. 11, in the virtual resonator represented as “NONE”, the average of frequency ratios is 2.37, and the average of coupling drive levels remains at 0.058 μW. At this time, the average of the Q values of vibration in the spurious mode is 21,835.

On the other hand, in the resonator 10 including the reducing film LM with the structure illustrated in FIG. 10, which is represented as “REDUCING FILM EXAMPLE”, the average of the Q values of vibration in the spurious mode is 4860, which is decreased to ¼ or less than the average of the Q values of the virtual resonator. In addition, the average of the frequency ratios has increased 2.70-fold, and the average of the coupling drive levels has increased to 0.125 μW.

In addition, the structure of the reducing film LM represented as “REDUCING FILM EXAMPLE” includes only the first layer 41 illustrated in FIG. 10. Even in this case, in the resonator 10, the Q value of vibration in the spurious mode has been decreased, the average of the frequency ratios has been increased, and the average of the coupling drive levels has been increased, compared with the virtual resonator.

As described above, since the support arm 151 has the reducing film LM that reduces the Q value of vibration of the support arm 151, the Q value of vibration in the spurious mode in which vibration of the support arm 151 is main vibration can be decreased, and the drive level at which coupling between vibration in the main mode and vibration in the spurious mode occurs can be increased. Since this makes coupling between vibration in the main mode and vibration in the spurious mode less likely to occur, coupling can be suppressed from occurring.

An example in which the vibrating portion 110 of the resonator 10 includes the four vibrating arms 121A to 121D used in the embodiment, but the present description is not limited to this example. The vibrating portion 110 may include, for example, three vibrating arms or five or more vibrating arms. In this case, at least two vibrating arms are subjected to out-of-plane bending in different phases.

In addition, an example in which one end of the support arm 151 of the resonator 10 is connected to the frame body 141D of the holding portion 140 is used in the embodiment, but the present description is not limited to this example. One end of the support arm 151 may be connected to, for example, the frame body 141C of the holding portion 140.

Exemplary embodiments of the present description have been set forth above. In the resonator according to one embodiment, the support arm has the reducing film that reduces the Q value of vibration of the support arm. As a result, the Q value of vibration in the spurious mode in which vibration of the support arm is main vibration can be decreased, and the drive level at which coupling between vibration in the main mode and vibration in the spurious mode occurs can be increased. Since this makes coupling between vibration in the main mode and vibration in the spurious mode less likely to occur, coupling can be suppressed from occurring.

In addition, in the resonator according to one embodiment, the thickness of the support arm including the reducing film is greater than the thickness of the arm portion of the vibrating arm. As a result, Young's modulus of the support arm including the reducing film can be increased, and the frequency in the spurious mode relative to the frequency in the main mode can be increased.

In addition, in the resonator according to one embodiment, the material of the reducing film differs from the material of the arm portions of the vibrating arms. As a result, the Q value of vibration in the spurious mode can be decreased while the Q value of vibration in the spurious mode is increased.

In addition, in the resonator according to one embodiment, the reducing film is formed on the support rear arm. As a result, the Q value in the spurious mode in which vibration of the support arm is main vibration can be decreased effectively and efficiently.

In addition, the resonating device according to one embodiment includes the resonator described above. As a result, the resonating device that suppresses coupling between vibration in the main mode and vibration in the spurious mode from occurring can be easily achieved.

In addition, in the resonating device described above, the reducing film includes a layer made of the material of the joint portion. As a result, since the reducing film can be formed by, for example, changing the shape of the mask or the like when layers that constitute the joint portion are formed, the reducing film can be easily formed without the manufacturing process of the resonator being added or changed.

It should be noted that the embodiments described above are intended to facilitate the understanding of the present description and are not intended to limit the interpretation of the present description. The present description may be modified or improved without departing from the spirit thereof, and the present description also includes equivalents thereof. That is, examples obtained by those skilled in the art making design changes to the embodiments and/or the modifications are also included within the scope of the present description as long as the examples have the characteristics of the present description. For example, elements in the embodiments and/or the modifications, the disposition, the material, the condition, the shape, and the size thereof are not limited to those illustrated and may be changed as appropriate. In addition, the embodiment and the modifications are examples, partial replacement or combination of the structures illustrated in different embodiments and/or modifications is possible, and these are also included in the scope of the present description as long as they include the characteristics of the present description.

### REFERENCE SIGNS LIST

1 resonating device
10 resonator
20 lower lid
21 recessed portion
22 bottom plate
23 side wall
30 upper lid
31 recessed portion
32 bottom plate
33 side wall
40 joint portion
41 first layer
42 second layer
43 third layer
44 fourth layer
50 projecting portion
110 vibrating portion
120 exciting portion
121, 121A, 121B, 121C, 121D vibrating arm
122, 122A, 122B, 122C, 122D weight portion
123, 123A, 123B, 123C, 123D arm portion
125, 125A, 125B, 125C, 125D mass-adding film
130 base portion
131A front-end portion
131B rear-end portion
131C left end portion
131D right end portion
140 holding portion
141A, 141B, 141C, 141D frame body
151 support arm
152 support rear arm
153 support side arm

1. A resonator comprising:
a vibrating portion including: three or more vibrating arms having respective fixed ends, at least two of the three or more vibrating arms being constructed for out-of-plane bending in different phases; and a base portion having a first end portion to which the fixed ends of the three or more vibrating arms are connected and a second end portion facing away from the first end portion;
a holding portion that holds the vibrating portion;
a support arm having a first end connected to the holding portion and a second end connected to the second end portion of the base portion; and
a reducing film on the support arm that reduces a Q value of vibration of the support arm.

2. The resonator according to claim 1, wherein a combined thickness of the support arm and the reducing film is greater than a thickness of arm portions of the three or more vibrating arms.

3. The resonator according to claim 1, wherein a material of the reducing film differs from a material of arm portions of the three or more vibrating arms.

4. The resonator according to claim 3, wherein the material of the reducing film comprises tetraethyl orthosilicate.

5. The resonator according to claim 1, wherein the support arm includes:
a support side arm having the first end connected to the holding portion; and
a support rear arm having the second end connected to the second end portion of the base portion and a third end connected to the support side arm.

6. The resonator according to claim 5, wherein the reducing film is at least on the support rear arm.

7. The resonator according to claim 5, wherein the reducing film is at least on the support side arm.

8. The resonator according to claim 5, wherein the reducing film is on both the support rear arm and the support side arm.

9. The resonator according to claim 5, wherein the support side arm extends parallel to at least one of the three or more vibrating arms.

10. The resonator according to claim 1, wherein the support arm is not line-symmetric with respect to a center line of the resonator in a plan view.

11. A resonating device comprising:
the resonator according to claim 1.

12. The resonating device according to claim 11, further comprising:
a lid body; and
a joint portion that joins the resonator and the lid body to each other.

13. The resonating device according to claim 12, wherein the reducing film includes a layer made of a material of the joint portion.

14. The resonating device according to claim 11, wherein a material of the reducing film differs from a material of arm portions of the three or more vibrating arms.

15. The resonator according to claim 14, wherein the material of the reducing film comprises tetraethyl orthosilicate.

16. The resonating device according to claim 11, wherein the support arm includes:
a support side arm having the first end connected to the holding portion; and
a support rear arm having the second end connected to the second end portion of the base portion and a third end connected to the support side arm.

17. The resonating device according to claim 16, wherein the reducing film is at least on the support rear arm.

18. The resonating device according to claim 16, wherein the reducing film is on both the support rear arm and the support side arm.

19. The resonating device according to claim 16, wherein the support side arm extends parallel to at least one of the three or more vibrating arms.

20. The resonating device according to claim 11, wherein the support arm is not line-symmetric with respect to a center line of the resonator in a plan view.
